(19) United States
(12) Patent Application Publication
(10) Pub. No.: US 2026/0164987 A1
(43) Pub. Date: Jun. 11, 2026

(54) DISPLAY PANEL, DISPLAY DEVICE HAVING THE SAME, AND ELECTRONIC DEVICE HAVING THE SAME

(71) Applicant: Samsung Display Co., Ltd., Yongin-si (KR)

(72) Inventors: YUN JANG, Yongin-si (KR); YOUNG GU KIM, Yongin-si (KR)

(21) Appl. No.: 19/178,171

(22) Filed: Apr. 14, 2025

(30) Foreign Application Priority Data
Jul. 10, 2024 (KR) 10-2024-0091251

(51) Int. Cl. H10K 59/80; G02B 27/01; H10H 20/832; H10H 20/833; H10H 29/856

(52) U.S. Cl. CPC H10K 59/80517; H10H 20/833; H10H 20/835; H10H 29/856; H10K 59/8791; G02B 27/0172

(57) ABSTRACT

A display panel includes a light-emitting diode. The light-emitting diode includes an anode electrode, a light-emitting layer, and a cathode electrode. The anode electrode includes a reflective layer configured to reflect incident light, a plurality of reflectors on (e.g., above) the reflective layer, and a top transparent electrode on the plurality of reflectors. Each of the plurality of reflectors extends in a first direction, and the plurality of reflectors are arranged in a second direction crossing the first direction. The light-emitting layer is on the anode electrode and configured to emit light of a set wavelength. The cathode electrode is on the light-emitting layer and configured to transmit a portion of the incident light while reflecting the other portion of the incident light. As a result, the light-emitting diode is configured to emit polarized light oscillating in a set direction.

### CROSS-REFERENCE TO RELATED APPLICATION

The present application claims priority to and benefit of Korean Patent Application No. 10-2024-0091251, filed on Jul. 10, 2024, in the Korean Intellectual Property Office, the entire content of which is incorporated herein by reference.

### BACKGROUND

### 1. Field

The present disclosure relates to a display panel and a display device, and for example, to a display panel and a display device including a light-emitting diode configured to emit polarized light.

### 2. Description of the Related Art

Head-mounted display devices are display devices that are worn on the head and may be utilized for implementing augmented reality or virtual reality. A head-mounted display device for implementing augmented reality may provide virtual graphic images through a translucent display device, allowing the user to concurrently (e.g., simultaneously) view the virtual graphic images and real-world objects, thereby experiencing augmented reality. A head-mounted display device for implementing virtual reality may provide different virtual graphic images to each of the user's eyes, allowing the user to experience virtual reality through the virtual contents provided to both eyes concurrently (e.g., simultaneously).

However, the weight of the head-mounted display device may place a burden on the user's body. Therefore, many efforts have been made to reduce the weight and size of head-mounted display devices.

Among those efforts, the method of utilizing pancake lenses allows for a reduction in weight and size of the head-mounted display device but has the shortcoming of low optical efficiency. Due to the structure of the pancake lens, it is necessary or desired to utilize polarized light, and an absorptive polarizing film is utilized. Because the absorptive polarizing film absorbs about half of the light emitted from the display device, there is a significant loss in optical efficiency.

### SUMMARY

Aspects of one or more embodiments of the present disclosure are directed toward a display panel and a display device with enhanced (e.g., improved) optical efficiency by including a light-emitting diode configured to emit polarized light without a polarizing film.

Additional aspects will be set forth in part in the description which follows and, in part, will be apparent from the description, or may be learned by practice of the presented embodiments of the disclosure.

According to one or more embodiments, a display panel may include a plurality of light-emitting diodes. A first light-emitting diode of the plurality of light-emitting diodes may include a first anode electrode, a first light-emitting layer, and a first cathode electrode. The first anode electrode may include a first reflective layer configured to reflect incident light, a plurality of first reflectors arranged on (e.g., above) the first reflective layer, and a first top transparent electrode arranged on the plurality of first reflectors. The plurality of first reflectors may each extend in a first direction, and the plurality of first reflectors may be arranged in a second direction crossing the first direction. The first light-emitting layer may be arranged on the first anode electrode and may be configured to emit light having a first wavelength. The first cathode electrode may be arranged on the first light-emitting layer and may be configured to transmit part of the incident light while reflecting another part of the incident light.

In one or more embodiments, along a third direction orthogonal to the first direction and the second direction, the optical distance between the first light-emitting layer and the plurality of first reflectors may be ¼ of the first wavelength. Along the third direction, the optical distance between the first light-emitting layer and the first reflective layer may be ½ of the first wavelength.

In one or more embodiments, along the third direction, the optical distance between the first light-emitting layer and the first cathode electrode may be ½ of the first wavelength.

In one or more embodiments, the amount of phase shift in the light reflected by the plurality of first reflectors may be defined as a first reflector phase shift amount (bs1). The amount of phase shift in the light reflected by the first reflective layer may be defined as a first reflective layer phase shift amount (ls1). Along the third direction, which is orthogonal to the first direction and the second direction, the optical distance (d11) between the first light-emitting layer and the plurality of first reflectors may satisfy the following mathematical expression 1. Along the third direction, the optical distance (d12) between the first light-emitting layer and the first reflective layer may satisfy the following mathematical expression 2.

$$d 11 = \frac{n λ 1 - bs 1}{2} \qquad Mathematical expression 1$$

where d11 is the optical distance between the first light-emitting layer and the plurality of first reflectors, n is an arbitrary integer, λ1 is the first wavelength, and bs1 is the first reflector phase shift amount.

$$d 12 = \frac{( n + \frac{1}{2} ) λ 1 - ls 1}{2} \qquad Mathematical expression 2$$

where d12 is the optical distance between the first light-emitting layer and the first reflective layer, n is an arbitrary integer, λ1 is the first wavelength, and ls1 is the first reflective layer phase shift amount.

In one or more embodiments, along the third direction, the optical distance (d13) between the first light-emitting layer and the first cathode electrode may satisfy the following mathematical expression 3.

$$d 13 = \frac{n λ 1}{2} \qquad Mathematical expression 3$$

where d13 is the optical distance between the first light-emitting layer and the first cathode electrode, n is an arbitrary integer, and λ1 is the first wavelength.

In one or more embodiments, the first light-emitting diode may be arranged on the first reflective layer and may further include a first transparent layer in contact with the first reflective layer. The first top transparent electrode may be in contact with the plurality of first reflectors. The refractive index of the first reflective layer may be higher than the refractive index of the first transparent layer. The refractive index of the first top transparent electrode may be lower than that of any one of the plurality of first reflectors.

In one or more embodiments, a first length of each of the plurality of first reflectors, measured in the second direction, may be between 2.5 nm and 100 nm, inclusive.

In one or more embodiments, a second length, measured between two adjacent first reflectors among the plurality of first reflectors, may be between 2.5 nm and 100 nm, inclusive (e.g., the second length is greater than or equal to 2.5 nm and smaller than or equal to 100 nm).

In one or more embodiments, a ratio of the first length to the second length may be between 0.95 and 1.05, inclusive (e.g., the ratio of the first length to second length is greater than or equal to 0.95 and smaller than or equal to 1.05).

In one or more embodiments, the first anode electrode may further include a first middle transparent electrode between (e.g., interposed between) the plurality of first reflectors and the first reflective layer.

In one or more embodiments, the first anode electrode may further include a first bottom transparent electrode arranged beneath (e.g., disposed below) the first reflective layer.

In one or more embodiments, a filler may be between two adjacent first reflectors among the plurality of first reflectors.

In one or more embodiments, a second light-emitting diode among the plurality of light-emitting diodes may include a second anode electrode, a second light-emitting layer, and a second cathode electrode. The second anode electrode may include a second reflective layer configured to reflect second incident light, a plurality of second reflectors arranged on the second reflective layer, and a second top transparent electrode arranged on the plurality of second reflectors. Each of the plurality of second reflectors may extend in the first direction, and the plurality of second reflectors may be arranged in the second direction. The second light-emitting layer may be arranged on the second anode electrode and may be configured to emit light having a second wavelength different from the first wavelength. The second cathode electrode may be arranged on the second light-emitting layer and may be configured to transmit part of the second incident light while reflecting another part of the second incident light.

In one or more embodiments, along the third direction, the optical distance between the second light-emitting layer and the plurality of second reflectors may be ¼ of the second wavelength. Along the third direction, the optical distance between the second light-emitting layer and the second reflective layer may be ½ of the second wavelength. Along the third direction, the optical distance between the second light-emitting layer and the second cathode electrode may be ½ of the second wavelength.

In one or more embodiments, a third light-emitting diode among the plurality of light-emitting diodes may include a third anode electrode, a third light-emitting layer, and a third cathode electrode. The third anode electrode may include a third reflective layer configured to reflect third incident light, a plurality of third reflectors arranged on the third reflective layer, and a third top transparent electrode arranged on the plurality of third reflectors. Each of the plurality of third reflectors may extend in the first direction, and the plurality of third reflectors may be arranged in the second direction. The third light-emitting layer may be arranged on the third anode electrode and may be configured to emit light having a third wavelength different from the first wavelength and the second wavelength. The third cathode electrode may be arranged on the third light-emitting layer and may include a third cathode electrode configured to transmits part of the third incident light and reflect another part of the third incident light. Along the third direction, the optical distance between the third light-emitting layer and the plurality of third reflectors may be ¼ of the third wavelength. Along the third direction, the optical distance between the third light-emitting layer and the third reflective layer may be ½ of the third wavelength. Along the third direction, the optical distance between the third light-emitting layer and the third cathode electrode may be ½ of the third wavelength.

According to one or more embodiments, a display device may include a display panel. The display panel may include a plurality of light-emitting diodes. A first light-emitting diode of the plurality of light-emitting diodes may include a first anode electrode, a first light-emitting layer, and a first cathode electrode. The first anode electrode may include a first reflective layer configured to reflect incident light, a plurality of first reflectors arranged on the first reflective layer, and a first top transparent electrode arranged on the plurality of first reflectors. The plurality of first reflectors may each extend in a first direction, and the plurality of first reflectors may be arranged in a second direction crossing the first direction. The first light-emitting layer may be arranged on the first anode electrode and may be configured to emit light having a first wavelength. The first cathode electrode may be arranged on the first light-emitting layer and may be configured to transmit part of the incident light while reflecting another part of the incident light.

In one or more embodiments, along a third direction orthogonal to the first direction and the second direction, the optical distance between the first light-emitting layer and the plurality of first reflectors may be ¼ of the first wavelength. Along the third direction, the optical distance between the first light-emitting layer and the first reflective layer may be ½ of the first wavelength. Along the third direction, the optical distance between the first light-emitting layer and the first cathode electrode may be ½ of the first wavelength.

In one or more embodiments, the display device may further include an optical system. The optical system may include a half-mirror lens and a polarizing mirror lens and may be configured to receive light emitted from the display panel. The half-mirror lens may include a half-mirror, which may be configured to reflect part of the received light and transmit another part of the received light. The polarizing mirror lens may include a polarizing mirror and a quarter-wave plate. The polarizing mirror may be configured to reflect light, among the received light, oscillating in a set or predetermined direction and transmit light, among the received light, oscillating in a direction different from the set or predetermined direction. The quarter-wave plate may be configured to alter a polarization direction of the received light. The quarter-wave plate may be between the polarizing mirror and the half-mirror lens.

In one or more embodiments, the display device may further include an optical system. The optical system may include a pancake lens and a polarizing mirror and may be configured to receive light emitted from the display panel. The pancake lens may include a half-mirror and a quarter-wave plate. The half-mirror may be configured to reflect part of the received light and transmit another part of the received light. The quarter-wave plate may be configured to alter the polarization direction of the received light. The polarizing mirror may be configured to reflect light, among the received light, oscillating in a set or predetermined direction and transmit light, among the received light, oscillating in a direction different from the set or predetermined direction. The quarter-wave plate may be between the polarizing mirror and the half-mirror lens.

According to one or more embodiments, an electronic device may include a display device including a display panel including a plurality of light-emitting diodes. A first light-emitting diode of the plurality of light-emitting diodes may include a first anode electrode, a first light-emitting layer, and a first cathode electrode. The first anode electrode may include a first reflective layer configured to reflect incident light, a plurality of first reflectors arranged on (e.g., above) the first reflective layer, and a first top transparent electrode arranged on the plurality of first reflectors. The plurality of first reflectors may each extend in a first direction, and the plurality of first reflectors may be arranged in a second direction crossing the first direction. The first light-emitting layer may be arranged on the first anode electrode and may be configured to emit light having a first wavelength. The first cathode electrode may be arranged on the first light-emitting layer and may be configured to transmit part of the incident light while reflecting another part of the incident light.

In one or more embodiments, the electronic device may include a mobile phone, a smartphone, a tablet personal computer (PC), a mobile communication terminal, an electronic organizer, an electronic book, a portable multimedia player (PMP), a navigation system, a navigation device, an ultra-mobile PC (UMPC), a television, a laptop, a monitor, an electric vehicle, a billboard, an Internet of Things (IoT) device, a smartwatch, a watch phone, or a head-mounted display (HMD).

According to one or more embodiments of the present disclosure, it is possible to provide a display panel that includes a light-emitting diode configured for emitting polarized light. As a result, it is possible to exclude an absorptive polarizing film in the display panel and the display device, and it is possible to provide the display panel and the display device with improved optical efficiency. For example, according to one or more embodiments of the present disclosure, a display panel can include light-emitting diodes (LEDs) configured to emit polarized light, eliminating the need for absorptive polarizing films. This enhances optical efficiency by preventing the light loss typically associated with such films. As a result, the display panel and device may achieve brighter and more vivid displays while reducing power consumption, which is particularly beneficial for portable devices like head-mounted displays, smartphones, and/or tablets. The detailed structural configurations of the LEDs, including the arrangement of electrodes and reflective layers, further enhance light emission and reflection, contributing to the overall improved performance and efficiency of the display technology.

### BRIEF DESCRIPTION OF THE DRAWINGS

The above and/or other aspects, features, and advantages of one or more embodiments of the present disclosure will become apparent from the following description, taken in conjunction with the accompanying drawings in which:

FIG. 1 is a perspective view illustrating a display device according to one or more embodiments of the present disclosure;

FIG. 2 illustrates an example of a user wearing the display device shown in FIG. 1;

FIG. 3 illustrates an example of a body portion, a cushion portion, a display panel, and an optical system of the display device shown in FIG. 1;

FIG. 4 is an example illustration of a portion of the display panel and optical system according to one or more embodiments of the present disclosure as well as a path of light emitted from the display panel;

FIG. 5 is an example illustration of a partial cross-section of the display panel according to one or more embodiments of the present disclosure;

FIG. 6 is an example magnified view of the AA section shown in FIG. 5;

FIG. 7 is an example illustration of a plurality of first reflectors and a first transparent layer according to one or more embodiments of the present disclosure;

FIG. 8 is an example magnified view of the BB section shown in FIG. 5;

FIG. 9 is an example magnified view of the CC section shown in FIG. 5;

FIG. 10 is an example illustration of a partial cross-section of a first light-emitting diode according to one or more embodiments of the present disclosure;

FIG. 11 is an example illustration of a partial cross-section of a first light-emitting diode according to one or more embodiments of the present disclosure;

FIG. 12 is an example illustration of a partial cross-section of a first light-emitting diode according to one or more embodiments of the present disclosure;

FIG. 13 is an example illustration of a partial cross-section of a first light-emitting diode according to one or more embodiments of the present disclosure;

FIG. 14 illustrates an example of a body portion, a cushion portion, a display panel, and an optical system of a display device;

FIG. 15 is a perspective view of a display device according to one or more embodiments of the present disclosure; and

FIG. 16 is an example illustration of a portion of the display panel and optical system according to one or more embodiments of the present disclosure as well as a path of light emitted from the display panel.

FIG. 17 is an exemplary block diagram of an electronic device according to one or more embodiments.

FIG. 18 illustrates schematic diagrams of electronic devices according to one or more embodiments.

### DETAILED DESCRIPTION

References will now be made in more detail to one or more embodiments, of which are illustrated in the accompanying drawings, where like reference numerals refer to like elements throughout, and duplicative descriptions thereof may not be provided. In this regard, the present embodiments may have a variety of forms and permutations, but the present disclosure should not be construed as being limited to the descriptions set forth herein. Rather, the present disclosure should be construed to encompass all forms, permutations, equivalents and substitutes covered by the technical ideas and scope of the present disclosure and equivalents thereof. Accordingly, one or more embodiments are merely described in more detail, by referring to the drawings, to explain aspects of the present disclosure. As used herein, the term “and/or” includes any and all combinations of one or more of the associated listed items.

As the disclosure allows for one or more suitable changes and numerous embodiments, certain embodiments will be illustrated in the drawings and described in the written description. Effects and features of the disclosure, and methods for achieving them will be clarified with reference to one or more embodiments described in more detail later in more detail with reference to the drawings. However, the disclosure is not limited to the following embodiments and may be embodied in one or more suitable forms.

While such terms as “first” and “second” may be used to describe one or more suitable components, such components must not be limited to the above terms. The above terms are used to distinguish one component from another.

The singular forms “a,” “an,” and “the” as used herein are intended to include the plural forms as well unless the context clearly indicates otherwise.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

In the present disclosure, if (e.g., when) one or more suitable elements such as a layer, a region, a plate, and/or the like are arranged “on” another element, not only the elements may be arranged “directly on” the other element, but another element may be arranged therebetween.

It will be understood that if (e.g., when) a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different directions that are not normal (e.g., perpendicular) to one another.

Like or substantially identical reference numerals refer to like or substantially identical elements. Moreover, in the accompanying drawings, the thicknesses, ratios, and dimensions of the elements may not be to exact scale and may have been exaggerated for the benefit of effective explanation of the technical aspects associated with these elements. As such, the present disclosure should not be restricted to the thicknesses, ratios, dimensions, and/or the like illustrated in the drawings.

If (e.g., when) an element is described to be “disposed on,” “placed on,” “arranged on,” “connected to,” or “coupled to” another element, it should be construed as being disposed on, placed on, arranged on, connected to, or coupled to the other element directly but also as possibly having another element therebetween. In contrast, if one element is described to be “directly arranged on,” “directly placed on,” “directly arranged on,” “directly connected to,” or “directly coupled to” another element, it should be construed that there is no other element interposed therebetween.

Moreover, relative terms, such as “below,” “under,” “beneath,” “lower,” “bottom,” “above,” “over,” “upper,” “top,” and/or the like, may be used herein to describe one element's relationship to another element as illustrated in the accompanying drawings. It should be understood that relative terms are intended to encompass different orientations of the device in addition to the orientation depicted in the accompanying drawings. For example, if the device in one of the drawings is turned over, elements described as being on the “lower” side of the other elements would then be oriented on “upper” sides of the other elements. The example term “lower” can therefore encompass an orientation of both (e.g., simultaneously) “lower” and “upper,” depending on the particular orientation of the drawing. Similarly, if the device in one of the drawings is turned over, elements described as “below” or “beneath” other elements would then be oriented “above” the other elements. The example term “below” or “beneath” can therefore encompass an orientation of both (e.g., simultaneously) above and.

Furthermore, if (e.g., when) one device or layer is described to be “on,” “over,” “above,” and/or the like, another device or layer, it shall also encompass the case of yet another device or layer arranged on, over, above, and/or the like, the other device or layer or interposed between the one device or layer and the other device or layer. In contrast, if (e.g., when) one device or layer is described to be “directly on,” “directly over,” “directly above,” and/or the like, another device or layer, it may refer to that no other device or layer is interposed between the one device or layer and the other device or layer.

An expression such as “have/has/having,” “comprise/comprises/comprising,” or “include/includes/including” is intended to designate a characteristic, a number, a step (e.g., act or task), an operation, an element, a part, and/or one or more (e.g., any suitable) combinations thereof, and should not be construed to preclude any possibility of presence or addition of one or more other characteristics, numbers, steps (e.g., act or task), operations, elements, parts, and/or one or more (e.g., any suitable) combinations thereof.

Unless otherwise defined, all terms, including technical terms and scientific terms, used herein have the same meaning as how they are generally understood by those of ordinary skill in the art to which the present disclosure pertains. Any term that is defined in a general dictionary should be construed to have the same meaning in the context of the relevant art, and, unless otherwise defined explicitly, should not be interpreted to have an idealistic or excessively (or substantially) formalistic meaning.

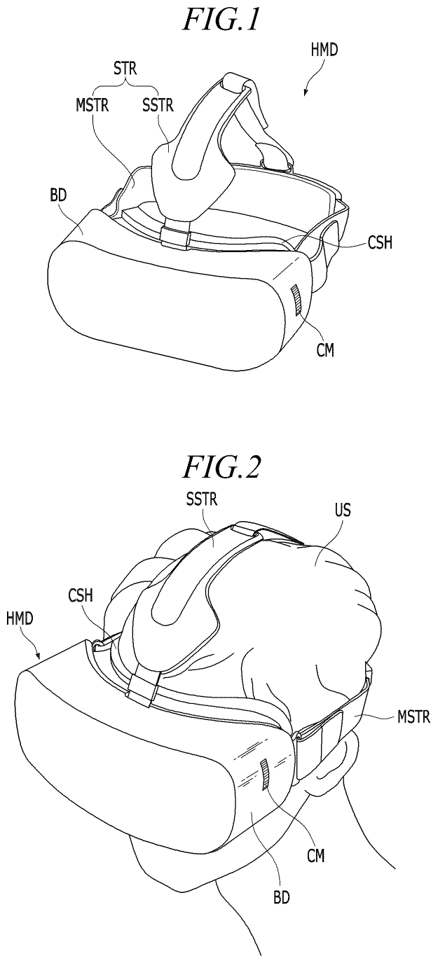

FIG. 1 is a perspective view illustrating a display device HMD according to one or more embodiments of the present disclosure, and FIG. 2 illustrates an example of a user US wearing the display device HMD shown in FIG. 1.

Referring to FIG. 1 and FIG. 2, the display device HMD may be a head-mounted display device that may be worn on the head of a user US. The display device HMD may be configured to provide images to the user US while blocking the user's peripheral view. Because the peripheral view is blocked, the user US wearing the display device HMD may be immersed in virtual reality more suitably (e.g., readily).

The display device HMD may include a body portion BD, a strap portion STR, and a cushion portion CSH.

The body portion BD may be a portion corresponding to the eyes of the user US. The body portion BD may house a control module CM. The control module CM may be used for adjusting volume, screen brightness, and/or the like and may be provided in the form of physical buttons, dials, a touchscreen, and/or the like.

The strap portion STR may be coupled to the body portion BD. The user US may use the strap portion STR to secure the body portion BD to the user's head. The strap portion STR may include a main strap MSTR and a sub-strap SSTR. The main strap MSTR may be worn around the circumference of the user's head, ensuring that the body portion BD is closely fitted to the head of the user US. The sub-strap SSTR may connect the body portion BD with the main strap MSTR across the top of the user's head. The sub-strap SSTR may be configured to prevent or stop the body portion BD from slipping down. Moreover, the sub-strap SSTR may be configured to distribute the weight of the body portion BD, providing the user US with enhanced comfort if (e.g., when) worn.

The cushion portion CSH may be arranged on one surface of the body portion BD. The one surface may be a surface that faces the user US if (e.g., when) the display device HMD is in use by the user US. The cushion portion CSH may include a material of which the shape is freely deformable. The cushion portion CSH may include a polymer resin. For example, the cushion portion CSH may include polyurethane, polycarbonate, polypropylene, and/or polyethylene or include a sponge formed by foaming materials such as rubber latex, urethane-based substances, and/or acrylic-based substances. However, the materials constituting the cushion portion CSH are not limited to these examples.

The cushion portion CSH may be configured to enhance the comfort of wearing the display device HMD. The cushion portion CSH may be detachable or attachable to the body portion BD. In one or more embodiments of the present disclosure, the cushion portion CSH may not be provided.

In one or more embodiments, the shape and usage of the display device HMD are not limited to the above description. For example, the display device HMD may take other shapes, such as glasses, sunglasses, or a helmet, which may be secured to the head of the user US. Moreover, the display device HMD may be configured to allow external light to pass through, enabling natural light to be incident at the eyes of the user US.

Furthermore, the display device HMD may not be mounted on the head of the user US. For instance, the display device HMD may be a tablet PC, a portable terminal, a laptop computer, a television, or a digital watch.

Furthermore, the display device HMD may be a part of a transportation means, such as a car, bicycle, motorcycle, train, boat, or airplane. For example, the display device HMD may be positioned, relative to a driver of a vehicle, in front of the steering wheel in the vehicle and utilized for displaying instrument panel information such as the vehicle's speed. The display device HMD may be also positioned on the dashboard of a vehicle to display control interfaces, audio settings, temperature, road conditions, and/or video information. The display device HMD may be positioned on either side of the driver's seat and the passenger seat and utilized as digital side rear-view mirrors. The display device HMD may be configured to display images captured from the vehicle's exterior. The display device HMD may be mounted on the back of the driver's and passenger's seats and utilized for displaying images for view by the rear-seat passengers, for example, video contents.

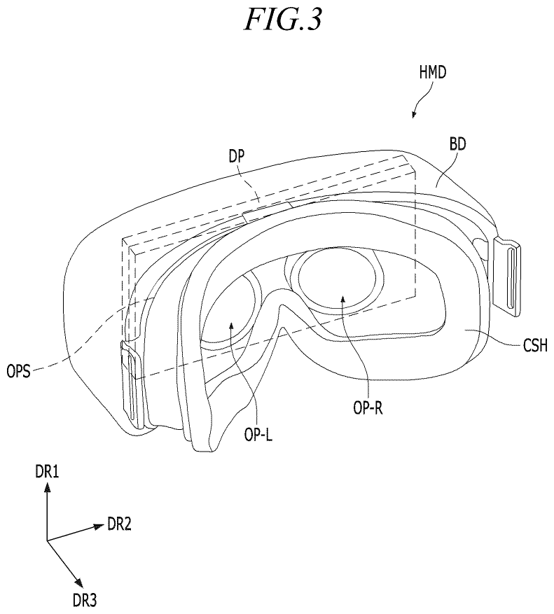

FIG. 3 illustrates an example of the body portion BD, the cushion portion CSH, a display panel DP, and an optical system OPS of the display device HMD shown in FIG. 1.

Referring to FIG. 3, the body portion BD may further house the display panel DP and the optical system OPS and may have two apertures OP-L, OP-R defined therein.

On one surface of the display panel DP, light may be emitted to display an image. For example, the light emitted from the display panel DP may be polarized. Moreover, a first image may be displayed on one portion of the display panel DP, and a second image may be displayed on another portion of the display panel DP.

The optical system OPS may be configured to refract and reflect the polarized light emitted from the display panel DP to guide the light toward the eyes of the user US (see FIG. 2). Additionally, the optical system OPS may be configured to make the image projected from the display panel DP appear distant from the eyes of the user US.

The two apertures OP-L, OP-R may include a left-eye aperture OP-L and a right-eye aperture OP-R. The left-eye aperture OP-L may be positioned to correspond to the left eye of the user US, and the right-eye aperture OP-R may be positioned to correspond to the right eye of the user US. The first and second images displayed on the display panel DP may be refracted and reflected by the optical system OPS and guided through the two apertures OP-L, OP-R, allowing the user US to view the first and second images.

Moreover, in the case where the first image and the second image are different from each other, these different images may be provided to the eye and right eye of the user US. As a result, the user US will perceive a sense of depth or spatiality from the different first and second images.

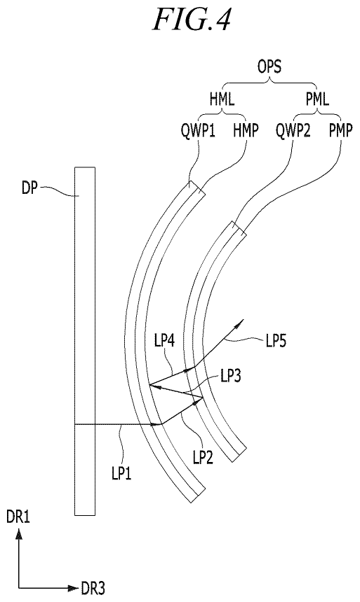

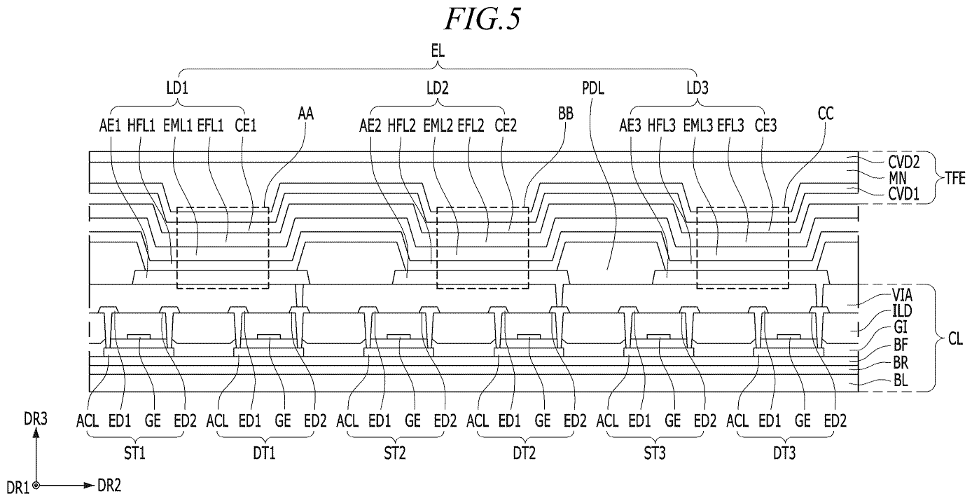

In one or more embodiments, in addition to the configuration shown in FIG. 4, the body portion BD may further accommodate, for example, an accelerometer, a proximity sensor, an optical sensor, and speakers.

FIG. 4 is an example illustration of a portion of the display panel DP and optical system OPS according to one or more embodiments of the present disclosure as well as a path of light emitted from the display panel DP.

Referring to FIG. 4, the optical system OPS may be a pancake lens including a half-mirror lens HML and a polarization mirror lens PML and may be positioned in front of the display panel DP. The light emitted from the display panel DP may travel along a first light path to a fifth light path LP1, LP2, LP3, LP4, LP5 before reaching the eye of the user US.

The half-mirror lens HML may include a first quarter-wave plate QWP1 and a half mirror HMP. The first quarter-wave plate QWP1 may be configured to alter the polarization direction of the received light. The half mirror HMP may be configured to reflect a portion of the incident light and allow another portion of the incident light to transmit.

The polarizing mirror lens PML may include a second quarter-wave plate QWP2 and a polarizing mirror PMP. The second quarter-wave plate QWP2 may be configured to alter the polarization direction of the received light. The polarizing mirror PMP may be configured to reflect light oscillating in a set or predetermined direction and allow light oscillating in a direction different from the set or predetermined direction to transmit.

The light emitted from the display panel DP may be incident at the first quarter-wave plate QWP1 along the first light path LP1. The polarization direction of light may be altered while the light passes through the first quarter-wave plate QWP1. A portion of the light having passed through the first quarter-wave plate QWP1 may be to transmit through the half mirror HMP, and another portion of the light may be reflected by the half mirror HMP.

The light having passed through the half mirror HMP along the second light path LP2 may be incident at the second quarter-wave plate QWP2. The polarization direction of light may be altered while the light passes through the second quarter-wave plate QWP2. A portion of the light oscillating in the set or predetermined direction after having passed through the second quarter-wave plate QWP2 may be reflected by the polarizing mirror PMP. In one or more embodiments, the light oscillating in a direction different from the set or predetermined direction may be to transmit through the polarizing mirror PMP.

The light reflected by the polarizing mirror PMP may follow the third light path LP3 and pass through the second quarter-wave plate QWP2. After having passed through the second quarter-wave plate QWP2, the light may be reflected by the half mirror HMP. The light reflected by the half mirror HMP may then travel along the fourth light path LP4, pass through the second quarter-wave plate QWP2 again and be incident at the polarizing mirror PMP.

The light incident on the polarizing mirror PMP along the fourth light path LP4 may have a different polarization direction from the light incident on the polarizing mirror PMP along the second light path LP2. This is because the light has passed through the second quarter-wave plate QWP2 twice in the process of passing through the third light path LP3 and the fourth light path LP4. Therefore, the light incident on the polarizing mirror PMP along the fourth light path LP4 may be to transmit through the polarizing mirror PMP.

The light having transmitted through the polarizing mirror PMP may be incident on the eyes of the user US, meaning that the image displayed on the display panel DP may be guided by the optical system OPS and provided to the user US. As a result, the display device HMD is capable of implementing virtual reality (VR).

FIG. 5 is an example illustration of a partial cross-section of the display panel DP according to one or more embodiments of the present disclosure.

Referring to FIG. 5, the display panel DP may include a circuit layer CL, a light-emitting diode layer EL, and an encapsulation layer TFE.

The circuit layer CL may include a base layer BL, a barrier layer BR, a buffer layer BF, a gate insulating layer GI, an interlayer dielectric ILD, a circuit insulating layer VIA, and a plurality of transistors ST1, ST2, ST3, DT1, DT2, DT3.

The plurality of transistors ST1, ST2, ST3, DT1, DT2, DT3 may each include an active portion ACL, a control electrode GE, a first electrode ED1, and a second electrode ED2.

The base layer BL may serve as the foundation of the circuit layer CL. For example, other components of the circuit layer CL may be stacked on the base layer BL.

The barrier layer BR may be arranged on (e.g., disposed on or above) the base layer BL. The barrier layer BR and the buffer layer BF may be configured to prevent or reduce impurities present in a lower layer from entering during the manufacturing process. For example, impurities are prevented or reduced from diffusing into the active portions ACL of the plurality of transistors ST1, ST2, ST3, DT1, DT2, DT3.

The buffer layer BF may be arranged on the barrier layer BR. The active portions ACL constituting each of the plurality of transistors ST1, ST2, ST3, DT1, DT2, DT3 may be arranged on the buffer layer BF. Each of the active portions ACL may contain polysilicon and/or amorphous silicon. In addition, the active portions ACL may contain a metal oxide semiconductor.

The active portions ACL may include a channel area, which is configured to function as a pathway for electrons and holes to travel, and a first ion doping area and a second ion doping area, which are arranged on either side of the channel area.

The gate insulating layer GI covering the active portions ACL may be arranged on the buffer layer BF. The gate insulating layer GI may include an organic film and/or an inorganic film. The gate insulating layer GI may include a plurality of inorganic thin films, which may include a silicon nitride layer and a silicon oxide layer.

The control electrodes GE, which constitute the plurality of transistors ST1, ST2, ST3, DT1, DT2, DT3, respectively, may be arranged on the gate insulating layer GI.

The interlayer dielectric ILD covering the control electrode GE may be arranged on the gate insulating layer GI. The interlayer dielectric ILD may include an organic film and/or an inorganic film. The interlayer dielectric ILD may include a plurality of inorganic thin films, which may include a silicon nitride layer and a silicon oxide layer.

The first electrodes ED1 and the second electrodes ED2 of the plurality of transistors ST1, ST2, ST3, DT1, DT2, DT3 may be arranged on the interlayer dielectric ILD.

The first electrodes ED1 and the second electrodes ED2 may each be connected to the corresponding active portions ACL through contact holes, which penetrate both (e.g., simultaneously) the gate insulating layer GI and the interlayer dielectric ILD.

The circuit insulating layer VIA covering the first electrodes ED1 and the second electrodes ED2 may be arranged on the interlayer dielectric ILD. The circuit insulating layer VIA may include an organic film and/or an inorganic film. The circuit insulating layer VIA may provide a flat surface. The circuit insulating layer VIA may be between (e.g., interposed between) a plurality of anode electrodes AE1, AE2, AE3 and the plurality of transistors ST1, ST2, ST3, DT1, DT2, DT3. A pixel defining layer PDL and a plurality of light-emitting diodes LD1, LD2, LD3 may be arranged on the circuit insulating layer VIA.

The plurality of transistors ST1, ST2, ST3, DT1, DT2, DT3 may include a plurality of driving transistors DT1, DT2, DT3 and a plurality of scan line transistors ST1, ST2, ST3. The driving transistors DT1, DT2, DT3 may be configured to control the amount of current flowing through the plurality of light-emitting diodes LD1, LD2, LD3 in response to a voltage applied to the plurality of control electrodes GE. The plurality of scan line transistors ST1, ST2, ST3 may be configured to apply electrical signals to the plurality of driving transistors DT1, DT2, DT3 by being turned on by signals received from scan lines.

The plurality of driving transistors DT1, DT2, DT3 may include a first driving transistor DT1, a second driving transistor DT2, and a third driving transistor DT3.

The first driving transistor DT1 may be configured to control the amount of current flowing through a first light-emitting diode LD1 in response to the voltage applied to the control electrode GE. Moreover, the second driving transistor DT2 may be configured to control the amount of current flowing through a second light-emitting diode LD2 in response to the voltage applied to the control electrode GE. Furthermore, the third driving transistor DT3 may be configured to control the amount of current flowing through a third light-emitting diode LD34 in response to the voltage applied to the control electrode GE.

The plurality of scan line transistors ST1, ST2, ST3 may include a first scan line transistor ST1, a second scan line transistor ST2, and a third scan line transistor ST #.

The first scan line transistor ST1 may be configured to apply electrical signals to the first driving transistor DT1 by being turned on by signals received from scan lines. Moreover, the second scan line transistor ST2 may be configured to apply electrical signals to the second driving transistor DT2 by being turned on by signals received from scan lines. Furthermore, the third scan line transistor ST3 may be configured to apply electrical signals to the third driving transistor DT3 by being turned on by signals received from scan lines.

Although the plurality of transistors ST1, ST2, ST3, DT1, DT2, DT3 are illustratively depicted in FIG. 5, the structure of the plurality of transistors ST1, ST2, ST3, DT1, DT2, DT3 is not limited to what is shown in FIG. 5. Although FIG. 5 is illustrated as if (e.g., when) the second electrodes ED2 of the plurality of driving transistors DT1, DT2, DT3 are directly contacting the plurality of anode electrodes AE1, AE2, AE3, this is due to the cross-sectional view, and in reality, each of the plurality of driving transistors DT1, DT2, DT3 may be connected to the plurality of anode electrodes AE1, AE2, AE3 via a transistor. However, the present disclosure is not limited to this configuration, and in one or more embodiments of the present disclosure, the second electrodes ED2 of the plurality of driving transistors DT1, DT2, DT3 may directly contact the plurality of anode electrodes AE1, AE2, AE3.

The light-emitting diode layer EL may include the pixel defining layer PDL, the first light-emitting diode LD1, the second light-emitting diode LD2, and the third light-emitting diode LD3.

The pixel defining layer PDL may be at (e.g., arranged in) a portion of the circuit insulating layer VIA. Accordingly, the plurality of apertures may be defined in other portions where the pixel defining layer PDL is not positioned.

Moreover, the plurality of light-emitting diodes LD1, LD2, LD3 may be formed in the plurality of apertures. The plurality of light-emitting diodes LD1, LD2, LD3 may include the first light-emitting diode LD1, the second light-emitting diode LD2, and the third light-emitting diode LD3.

The first light-emitting diode LD1 may include a first anode electrode AE1, a first hole functional layer HFL1, a first light-emitting layer EML1, a first electron functional layer EFL1, and a first cathode electrode CE1. The first light-emitting layer EML1 may be configured to emit polarized light.

The first anode electrode AE1 may be configured to receive electrical signals from the first driving transistor DT1 and the first scan line transistor ST1.

The first anode electrode AE1 may be configured to reflect the light emitted from the first light-emitting layer EML1. This configuration will be described in more detail with reference to another drawing.

The first hole functional layer HFL1 may be configured to assist the movement of holes generated by the first anode electrode AE1. For example, the first hole functional layer HFL1 may be configured to receive the holes injected from the first anode electrode AE1 more suitably (e.g., readily) and facilitate the movement of the holes. The first hole functional layer HFL1 may have a multi-layer structure. For example, the first hole functional layer HFL1 may further include a hole injection layer and a hole transport layer.

The first light-emitting layer EML1 may be configured to emit light. The first light-emitting layer EML1 may be configured to emit monochromatic light having a peak wavelength. Moreover, the wavelength of the light emitted from the first light-emitting layer EML1 may be defined as a first wavelength. In addition, the first light-emitting layer EML1 may include organic light-emitting materials or quantum dots. Therefore, the first light-emitting diode LD1 may be an Organic Light Emitting Diode (OLED) or a Quantum dot Light Emitting Diode (QLED).

The first hole functional layer HFL1 may be configured to assist the movement of holes generated by the first anode electrode AE1. For example, the first hole functional layer HFL1 may be configured to receive the holes injected from the first anode electrode AE1 more suitably (e.g., readily) and facilitate the movement of the holes. The first hole functional layer HFL1 may have a multi-layer structure. For example, the first hole functional layer HFL1 may have a structure further including a hole injection layer and a hole transport layer.

The first cathode electrode CE1 has low resistance, and thus current may suitably (e.g., readily) flow. Additionally, the first cathode electrode CE1 may be configured to transmit some of the incident light while reflecting the rest. For example, the first cathode electrode CE1 may have properties similar to those of a half mirror.

The second light-emitting diode LD2 may include a second anode electrode AE2, a second hole functional layer HFL2, a second light-emitting layer EML2, a second electron functional layer EFL2, and a second cathode electrode CE2. The second light-emitting diode LD2 may be configured to emit polarized light.

The second light-emitting diode LD2 may be described primarily in terms of differences from the first light-emitting diode LD1. The wavelength of light emitted by the second light-emitting layer EML2 may be different from the wavelength of light emitted by the first light-emitting layer EML1. For example, the wavelength of light emitted by the second light-emitting layer EML2 may be defined as a second wavelength.

The third light-emitting diode LD3 may include a third reflective layer RFL3, a third transparent layer TL3, a third anode electrode AE3, a third hole functional layer HFL3, a third light-emitting layer EML3, a third electron functional layer EFL3, and a third cathode electrode CE3. The third light-emitting diode LD3 may be configured to emit polarized light.

The third light-emitting diode LD3 may be described primarily in terms of differences from the first light-emitting diode LD1 and the second light-emitting diode LD2. The wavelength of light emitted by the third light-emitting layer EML3 may be different from the wavelengths of light emitted by the first light-emitting layer EML1 and the second light-emitting layer EML2. For example, the wavelength of light emitted by the third light-emitting layer EML3 may be defined as a third wavelength.

The encapsulation layer TFE may be configured to protect the plurality of light-emitting diodes LD1, LD2, LD3 by sealing the plurality of light-emitting diodes LD1, LD2, LD3 from external oxygen or moisture.

The encapsulation layer TFE may include a first inorganic encapsulation layer CVD1, an organic encapsulation layer MN, and a second inorganic encapsulation layer CVD2. While the encapsulation layer TFE in FIG. 5 is illustrated to include two inorganic encapsulation layers CVD1, CVD2 and one organic encapsulation layer MN, the present disclosure is not limited to this configuration. For instance, the encapsulation layer TFE may include three inorganic encapsulation layers and two organic encapsulation layers, in which case the inorganic encapsulation layers and the organic encapsulation layers may be alternately stacked.

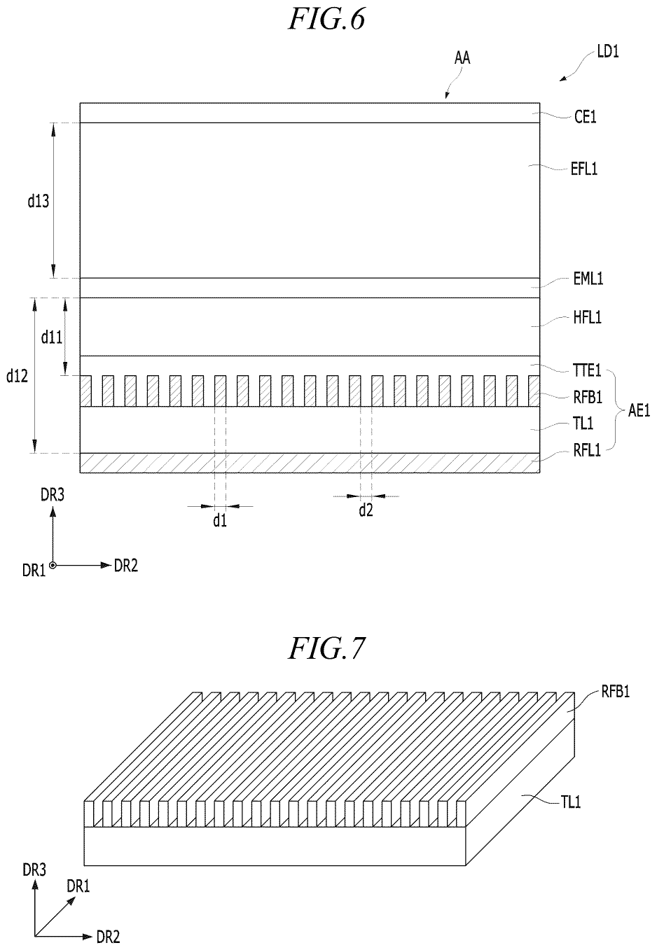

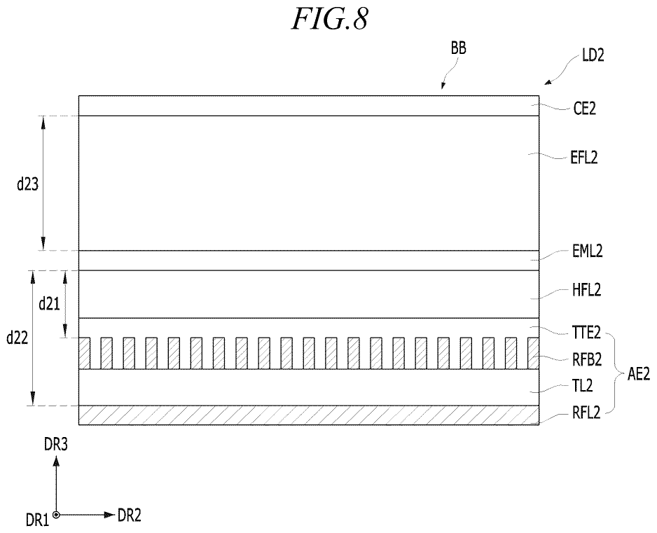

FIG. 6 is an example magnified view of the AA section shown in FIG. 5. FIG. 7 is an example illustration of a plurality of first reflectors RFB1 and a first transparent layer TL1 according to one or more embodiments of the present disclosure.

Referring to FIG. 6, the first light-emitting diode LD1 may include the first anode electrode AE1, the first hole functional layer HFL1, the first light-emitting layer EML1, the first electron functional layer EFL1, and the first cathode electrode CE1.

The first anode electrode AE1 may include a first reflective layer RFL1, a first transparent layer TL1, a plurality of first reflectors RFB1, and a first top transparent electrode TTE1.

The optical distance between the first light-emitting layer EML1 and the plurality of first reflectors RFB1 may be defined as a first polarizing mirror distance (d11). The optical distance between the first light-emitting layer EML1 and the first reflective layer RFL1 may be defined as a first mirror distance (d12). The optical distance between the first light-emitting layer EML1 and the first cathode electrode CE1 may be defined as a first half-mirror distance (d13).

The first reflective layer RFL1 may be configured to reflect incident light. The first reflective layer RFL1 may be a layered structure that includes silver (Ag). The first reflective layer RFL1 may be configured to reflect light in all polarization states, regardless of the polarization direction of the incident light. Additionally, the phase of the light reflected by the first reflective layer RFL1 may be altered. The amount of phase shift in the light reflected by the first reflective layer RFL1 may be defined as a first reflective layer phase shift amount (ls1). The first reflective layer phase shift amount (ls1) may be proportional to the wavelength of the incident light. For example, the first reflective layer phase shift amount (ls1) may be one-half of the wavelength of the incident light.

The refractive index of the first reflective layer RFL1 may be higher than the refractive index of the first transparent layer TL1. As a result, the phase of the light that has passed through the first transparent layer TL1 may be altered if (e.g., when) the light is reflected by the first reflective layer RFL1.

The first transparent layer TL1 may be arranged on the first reflective layer RFL1 and may be configured to transmit light. Accordingly, the first transparent layer TL1 may not interfere with the light emitted from the first light-emitting layer EML reaching and being reflected by the first reflective layer RFL1. Furthermore, the first transparent layer TL1 may include a dielectric material.

The plurality of first reflectors RFB1 may be arranged on the first transparent layer TL1 and may be configured to reflect incident light. The plurality of first reflectors RFB1 may be a structure arranged with a plurality of linear structures that include silver (Ag). For example, as shown in FIG. 7, each of the plurality of first reflectors RFB1 may extend in a first direction DR1. Moreover, the plurality of first reflectors RFB1 may be arranged in a second direction DR2 intersecting the first direction DR1. For example, the plurality of first reflectors RFB1 may form a wire grid polarizer. Accordingly, the plurality of first reflectors RFB1 may reflect light oscillating in the direction in which each reflector extends, for example, the first direction DR1, while allowing light oscillating in the second direction DR2 to pass through.

For example, a first length (d1) of each of the plurality of first reflectors RFB1, measured in the second direction DR2, may be between 2.5 nm and 100 nm, inclusive, e.g., the first length (d1) may be greater than or equal to 2.5 nm and smaller than or equal to 100 nm. Moreover, a second length (d2), measured between two adjacent first reflectors RFB1 of the plurality of first reflectors RFB1, may be between 2.5 nm and 100 nm, inclusive, e.g., the second length (d2) may be greater than or equal to 2.5 nm and smaller than or equal to 100 nm. Furthermore, the ratio of the first length (d1) to the second length (d2) may be between 0.95 and 1.05, inclusive, e.g., the ratio of the first length (d1) to the second length (d2) may be greater than or equal to 0.95 and smaller than or equal to 1.05. For example, the width of each of the plurality of first reflectors RFB1 and the spacing between two adjacent first reflectors of the plurality of first reflectors RFB1 (e.g., a distance between two adjacent first reflectors) may be substantially the same. Based on the configuration disclosed above, it becomes possible to further enhance the degree of polarization of the light reflected by the plurality of first reflectors RFB1. For example, the degree of polarization of the light reflected by the plurality of first reflectors RFB1 may be 95% or higher.

Additionally, the phase of the light reflected by the plurality of first reflectors RFB1 may be altered. The amount of phase shift in the light reflected by the plurality of first reflectors RFB1 may be defined as a first reflector phase shift amount (bs1). The first reflector phase shift amount (bs1) may be proportional to the wavelength of the incident light. For example, the first reflector phase shift amount (bs1) may be one-half of the wavelength of the incident light.

The refractive index of the plurality of first reflectors RFB1 may be higher than the refractive index of the first top transparent electrode TTE1. Accordingly, the phase of the light having passed through the first top transparent electrode TTE1 may be altered if (e.g., when) reflected by the plurality of first reflectors RFB1.

The first top transparent electrode TTE1 may be arranged on the plurality of first reflectors (RFB1) and may have low resistance, allowing current to flow suitably. Moreover, the first top transparent electrode TTE1 may be transparent. Accordingly, the first top transparent electrode TTE1 may not interfere with the light emitted from the first light-emitting layer EML reaching and being reflected by the first reflective layer RFL1 and the plurality of first reflectors RFB1. In one or more embodiments, the first top transparent electrode TTE1 may include indium tin oxide, which provides the aforementioned material characteristics, e.g., low resistance and transparent. Moreover, the first top transparent electrode TTE1 may be arranged in contact with the plurality of first reflectors RFB1 to prevent or reduce the plurality of first reflectors RFB1 from corrosion.

The descriptions of the first hole functional layer HFL1, the first light-emitting layer EML1, the first electron functional layer EFL1, and the first cathode electrode CE1 may be substantially the same as those provided with reference to FIG. 5.

In FIG. 6, the first polarizing mirror distance (d11), the first mirror distance (d12), and the first half-mirror distance (d13) are depicted as physical distances between the elements. However, the first polarizing mirror distance (d11), the first mirror distance (d12), and the first half-mirror distance (d13) may actually represent optical distances. Optical distance may be defined as the distance light would travel in a vacuum in substantially the same amount of time it takes to travel through a medium. The optical distance may be calculated as the product of the physical distance light travels and the refractive index of the path through which the light passes.

The first polarizing mirror distance (d11) may satisfy the following Mathematical Expression 1.

$$d 11 = \frac{n \times λ 1 - bs 1}{2} \qquad Mathematical Expression 1$$

where d11 is the optical distance between the first light-emitting layer EML1 and the plurality of first reflectors RFB1, n is an integer, λ1 is the first wavelength, and bs1 is the first reflector phase shift amount.

Mathematical Expression 1 may be derived from the following Mathematical Expression 1-a.

$$2 \times d 11 + bs 1 = n \times λ 1 \qquad Mathematical Expression 1 - a$$

For example, the light emitted from the first light-emitting layer EML1 may travel a distance corresponding to the first polarizing mirror distance (d11) as it reaches the plurality of first reflectors RFB1. Additionally, the phase of the emitted light may be altered by the first reflector phase shift amount (bs1) as it is reflected by the plurality of first reflectors RFB1. Moreover, the light reflected by the plurality of first reflectors RFB1 may then travel a distance corresponding to the first polarizing mirror distance (d11) as it reaches the first light-emitting layer EML1. As a result, the left side of [Mathematical Expression 1-a] (e.g., 2×d11+bs1) may represent an amount of phase shift experienced by the light emitted from the first light-emitting layer EML1 as it is reflected by the plurality of first reflectors RFB1 and returns to the first light-emitting layer EML1. This amount of phase shift may be set to be an integer multiple of the first wavelength (λ1), so that the phase of the light initially emitted from the first light-emitting layer EML1 and the phase of the light reflected by the plurality of first reflectors RFB1 and returning to the first light-emitting layer EML1 may each independently be the same.

For example, if (e.g., when) the first reflector phase shift amount (bs1) is half of the wavelength of the incident light, the first polarizing mirror distance (d11) may satisfy the following Mathematical Expression 1-b.

$$d 11 = \frac{n \times λ 1 - \frac{1}{2} \times λ 1}{2} \qquad Mathematical Expression 1 - b$$

If (e.g., when) 1 is substituted for n in Mathematical Expression 1-b, the first polarizing mirror distance (d11) may be one-fourth of the first wavelength (λ1).

The first mirror distance (d12) may satisfy the following Mathematical Expression 2.

$$d 12 = \frac{( n + \frac{1}{2} ) \times λ 1 - ls 1}{2} \qquad Mathematical Expression 2$$

where d12 is the optical distance between the first light-emitting layer EML1 and the first reflective layer RFL1, n is an integer, λ1 is the first wavelength, and ls1 is the first reflective layer phase shift amount.

The above Mathematical Expression 2 may be derived from the following Mathematical Expression 2-a.

$$2 \times d 12 + ls 1 = ( n + \frac{1}{2} ) \times λ 1 \qquad Mathematical Expression 2 - a$$

For example, the light emitted from the first light-emitting layer EML1 may travel a distance corresponding to the first mirror distance (d12) as it reaches the first reflective layer RFL1. Additionally, the phase of the emitted light may be altered by the first reflective layer phase shift amount (ls1) as it is reflected by the first reflective layer RFL1. The light reflected by the first reflective layer RFL1 may travel a distance corresponding to the first mirror distance (d12) as it returns to the first light-emitting layer EML1. As a result, the left side of [Mathematical Expression 2-a] (e.g., 2×d12+ls1) may represent the amount of phase shift experienced by the light emitted from the first light-emitting layer EML1 as it is reflected by the first reflective layer RFL1 and returns to the first light-emitting layer EML1. This amount of phase shift may be set to be an integer multiple of the first wavelength (λ1) plus one-half of the first wavelength (λ1), so that the phase of the light emitted from the first light-emitting layer EML1 and the phase of the light reflected by the first reflective layer RFL1 and returning to the first light-emitting layer EML1 may be opposite to each other.

For example, if (e.g., when) the first reflective layer phase shift amount (ls1) is half of the wavelength of the incident light, the first mirror distance (d12) may satisfy the following Mathematical Expression 2-b.

$$d 12 = \frac{n \times λ 1}{2} \qquad Mathematical Expression 2 - b$$

If (e.g., when) 1 is substituted for n in the above Mathematical Expression 2-b, the first mirror distance (d12) may be one-half of the first wavelength (λ1).

The first half-mirror distance (d13) may satisfy the following Mathematical Expression 3.

$$d 13 = \frac{n λ 1}{2} \qquad Mathematical Expression 3$$

where d13 is the optical distance between the first light-emitting layer EML1 and the first cathode electrode CE1, n is an integer, and λ1 is the first wavelength.

For example, the first half-mirror distance (d13) may be one-half of the first wavelength (λ1). The above Mathematical Expression 3 may be derived from the following Mathematical Expression 3-a.

$$2 \times d 13 = n \times λ 1 \qquad Mathematical Expression 3 - a$$

For example, the light emitted from the first light-emitting layer EML1 may travel a distance corresponding to the first half-mirror distance (d13) as it reaches the first cathode electrode CE1. Additionally, the phase of the emitted light may not change if (e.g., when) it is reflected by the first cathode electrode CE1. The light reflected by the first cathode electrode CE1 may then travel a distance corresponding to the first half-mirror distance (d13) as it returns to the first light-emitting layer EML1. As a result, the left side of [Mathematical Expression 3-a] (e.g., 2×d13) may represent the amount of phase shift experienced by the light emitted from the first light-emitting layer EML1 as it is reflected by the first cathode electrode CE1 and returns to the first light-emitting layer EML1. This amount of phase shift may be set to be an integer multiple of the first wavelength (λ1), so that the phase of the light initially emitted from the first light-emitting layer EML1 and the phase of the light reflected by the first cathode electrode CE1 and returning to the first light-emitting layer EML1 may be substantially the same.

Moreover, a microcavity may be formed between the plurality of first reflectors RFB1 and the first cathode electrode CE1. The luminous intensity of light emitted from the microcavity may be expressed by the following Mathematical Expression 4.

$$Ie ( d 11 , d 13 ) = \frac{( 1 - Rh ) \times [ \begin{matrix}1 + Rb + 2 \sqrt{Rb} \times cos \\ ( \frac{4 π \times d 11 + 2 π \times bs 1}{λ 1} )\end{matrix} ]}{\begin{matrix}1 + Rb \times Rh - 2 \sqrt{Rb \times Rh} \times \\ cos ( \frac{4 π \times ( d 11 + d 13 ) + 2 π \times bs 1}{λ 1} )\end{matrix}} Ii \qquad Mathematical Expression 4$$

where Ie is the luminous intensity of light emitted outside the first cathode electrode CE1, d11 is the optical distance between the first light-emitting layer EML1 and the plurality of first reflectors RFB1, d13 is the optical distance between the first light-emitting layer EML1 and the first cathode electrode CE1, Rh is the reflectivity of the first cathode electrode CE1, Rb is the reflectivity of the plurality of first reflectors RFB1, λ1 is the first wavelength, and Ii is the luminous intensity of light inside the first light-emitting diode LD1.

The value from [Mathematical Expression 1] may be substituted for the value of the first polarizing mirror distance (d11), and the value from [Mathematical Expression 3] may be substituted for the value of the first half-mirror distance (d13). The result of these substitutions may be expressed by the following Mathematical Expression 4-a.

$$Ie ( d 11 , d 13 ) = \frac{( 1 - Rb ) \times [ 1 + Rb + 2 \sqrt{Rb} \times cos ( 2 π n ) ]}{1 + Rb \times Rh - 2 \sqrt{Rb \times Rh} \times cos ( 2 π n )} Ii \qquad Mathematical Expression 4 - a$$

In [Mathematical Expression 4-a], the cosine values may all be equal to 1. Therefore, the numerator representing the luminous intensity of light emitted outside the first cathode electrode CE1 may reach its maximum value, and the denominator may reach its minimum value, thereby maximizing or increasing the luminous intensity of light emitted outside the first cathode electrode CE1. Moreover, a resonance phenomenon of light may occur within the microcavity. For example, the light resonating within the microcavity may be the light reflected by the plurality of first reflectors RFB1. For example, the resonating light may be light oscillating in the first direction DR1 and may be polarized.

In one or more embodiments, another microcavity may be formed between the first reflective layer RFL1 and the first cathode electrode CE1. The luminous intensity of light emitted from the microcavity may be expressed by the following Mathematical Expression 5.

$$Ie ( d 12 , d 13 ) = \frac{( 1 - Rh ) \times [ \begin{matrix}1 + Rl + 2 \sqrt{Rl} \times cos \\ ( \frac{4 π \times d 12 + 2 π \times ls 1}{λ 1} )\end{matrix} ]}{\begin{matrix}1 + Rl + \times Rh - \\ 2 \sqrt{Rl \times Rh} cos ( \frac{4 π \times ( d 12 + d 13 ) + 2 π \times ls 1}{λ 1} )\end{matrix}} Ii \qquad Mathematical Expression 5$$

where Ie is the luminous intensity of light emitted outside the first cathode electrode CE1, d12 is the optical distance between the first light-emitting layer EML1 and the first reflective layer RFL1, d13 is the optical distance between the first light-emitting layer EML1 and the first cathode electrode CE1, Rh is the reflectivity of the first cathode electrode CE1, R/is the reflectivity of the first reflective layer RFL1, λ1 is the first wavelength, and Ii is the luminous intensity of light inside the first light-emitting diode LD1.

The value from [Mathematical Expression 2] may be substituted for the value of the first mirror distance (d12), and the value from [Mathematical Expression 3] may be substituted for the value of the first half-mirror distance (d13). The result of these substitutions may be expressed by the following Mathematical Expression 5-a.

$$Ie ( d 12 , d 13 ) = \frac{( 1 - Rh ) \times [ \begin{matrix}1 + Rl + 2 \sqrt{Rl} \times cos \\ ( 2 π n + π )\end{matrix} ]}{1 + Rl + \times Rh - 2 \sqrt{Rl \times Rh} cos ( 2 π n \times π )} Ii \qquad Mathematical Expression 5 - a$$

In [Mathematical Expression 5-a], the cosine values may all be equal to −1. Therefore, the numerator representing the luminous intensity of light emitted outside the first cathode electrode CE1 may become its minimum value, and the denominator may become its maximum value, thereby minimizing or reducing the luminous intensity of light emitted outside the first cathode electrode CE1. For example, the light with minimized or reduced luminous intensity may be the light that passes through the plurality of first reflectors RFB1 and is reflected by the first reflective layer RFL1. For example, the light with minimized or reduced luminous intensity may be light oscillating in a direction other than the first direction DR1, for example, the second direction DR2, and may be polarized.

Accordingly, within the first light-emitting diode LD1, the light oscillating in the first direction DR1 may resonate. In contrast, the light oscillating in the second direction DR2 within the first light-emitting diode LD1 may be minimized or reduced. Thus, the Purcell effect may be induced, resulting in the emission of light oscillating in the first direction DR1 from the first light-emitting layer EML1. For example, within the first light-emitting layer EML1, the decay rate of excitons oscillating in the first direction DR1 may increase, leading to the enhanced emission of light oscillating in the first direction DR1.

FIG. 8 is an example illustration of a portion of the cross-section BB of the second light-emitting diode LD2 according to one or more embodiments of the present disclosure. Referring to FIG. 8, the second light-emitting diode LD2 may include the second anode electrode AE2, the second hole functional layer HFL2, the second light-emitting layer EML2, the second electron functional layer EFL2, and the second cathode electrode CE2.

The second anode electrode AE2 may include a second reflective layer RFL2, a second transparent layer TL2, a plurality of second reflectors RFB2, and a second top transparent electrode TTE2.

The optical distance between the second light-emitting layer EML2 and the plurality of second reflectors RFB2 may be defined as a second polarizing mirror distance (d21). Moreover, the optical distance between the second light-emitting layer EML2 and the second reflective layer RFL2 may be defined as a second mirror distance (d22). The optical distance between the second light-emitting layer EML2 and the second cathode electrode CE2 may be defined as a second half-mirror distance (d23).

The second light-emitting layer EML2 may be configured to emit light of a second wavelength different from the first wavelength. Accordingly, the second polarizing mirror distance (d21) may differ from the first polarizing mirror distance (d11). Moreover, the second mirror distance (d22) may differ from the first mirror distance (d12). Furthermore, the second half-mirror distance (d23) may differ from the first half-mirror distance (d13).

The amount of phase shift in the light reflected by the second reflective layer RFL2 may be defined as a second reflective layer phase shift amount (ls2). The second reflective layer phase shift amount (ls2) may be proportional to the wavelength of the incident light. For example, the second reflective layer phase shift amount (ls2) may be one-half of the wavelength of the incident light.

Moreover, the phase of the light reflected by the plurality of second reflectors RFB2 may be altered. The amount of phase shift in the light reflected by the plurality of second reflectors RFB2 may be defined as a second reflector phase shift amount (bs2). The second reflector phase shift amount (bs2) may be proportional to the wavelength of the incident light. For example, the second reflector phase shift amount (bs2) may be one-half of the wavelength of the incident light.

Moreover, the second polarizing mirror distance (d21) may satisfy the following Mathematical Expression 6, and the second polarizing mirror distance (d21) may be one-fourth of the second wavelength (λ2).

$$d 21 = \frac{n \times λ 2 - bs 2}{2} \qquad Mathematical Expression 6$$

where d21 is the optical distance between the second light-emitting layer EML2 and the plurality of second reflectors RFB2, n is an integer, λ2 is the second wavelength, and bs2 is the second reflector phase shift amount.

The second mirror distance (d22) may satisfy the following Mathematical Expression 7, and the second mirror distance (d22) may be one-half of the second wavelength (λ2).

$$d 22 = \frac{( n + \frac{1}{2} ) \times λ 2 - ls 2}{2} \qquad Mathematical Expression 7$$

where d22 is the optical distance between the second light-emitting layer EML2 and the second reflective layer RFL2, n is an integer, λ2 is the second wavelength, and ls2 is the second reflective layer phase shift amount.

The second half-mirror distance (d23) may satisfy the following Mathematical Expression 8, and the second half-mirror distance (d23) may be one-half of the second wavelength (λ2).

$$d 23 = \frac{n \times λ 2}{2} \qquad Mathematical Expression 8$$

where d23 is the optical distance between the second light-emitting layer EML2 and the second cathode electrode CE2, n is an integer, and λ2 is the second wavelength.

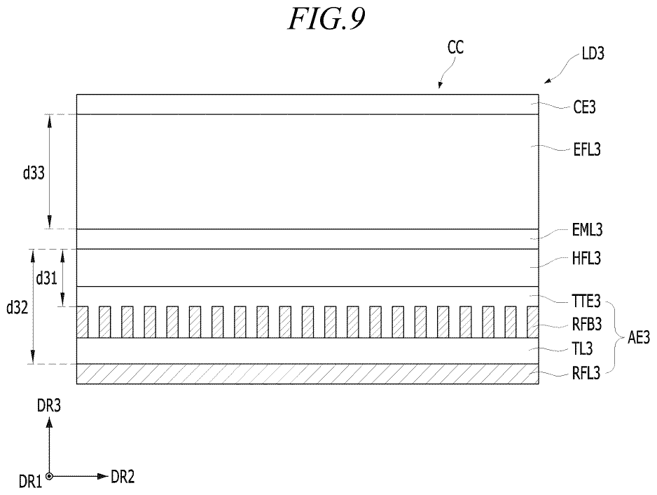

FIG. 9 is an example illustration of a portion of the cross-section CC of the third light-emitting diode LD3 according to one or more embodiments of the present disclosure. Referring to FIG. 9, the third light-emitting diode LD3 may include the third anode electrode AE3, the third hole functional layer HFL3, the third light-emitting layer EML3, the third electron functional layer EFL3, and the third cathode electrode CE3.

The third anode electrode AE3 may include the third reflective layer RFL3, the third transparent layer TL3, a plurality of third reflectors RFB3, and a third top transparent electrode TTE3.

The optical distance between the third light-emitting layer EML3 and the plurality of third reflectors RFB3 may be defined as a third polarizing mirror distance (d31). Moreover, the optical distance between the third light-emitting layer EML3 and the third reflective layer RFL3 may be defined as a third mirror distance (d32). The optical distance between the third light-emitting layer EML3 and the third cathode electrode CE3 may be defined as a third half-mirror distance (d33).

The third light-emitting layer EML3 may be configured to emit light of a third wavelength different from the first and second wavelengths. Accordingly, the third polarizing mirror distance (d31) may differ from the first polarizing mirror distance (d11) and the second polarizing mirror distance (d21). Moreover, the third mirror distance (d32) may differ from the first mirror distance (d12) and the second mirror distance (d22). Furthermore, the third half-mirror distance (d33) may differ from the first half-mirror distance (d13) and the second half-mirror distance (d23).

The amount of phase shift in the light reflected by the third reflective layer RFL3 may be defined as a third reflective layer phase shift amount (ls3). The third reflective layer phase shift amount (ls3) may be proportional to the wavelength of the incident light. For example, the third reflective layer phase shift amount (ls3) may be one-half of the wavelength of the incident light.

Additionally, the phase of the light reflected by the plurality of third reflectors RFB3 may be altered. The amount of phase shift in the light reflected by the plurality of third reflectors RFB3 may be defined as a third reflector phase shift amount (bs3). The third reflector phase shift amount (bs3) may be proportional to the wavelength of the incident light. For example, the third reflector phase shift amount (bs3) may be one-half of the wavelength of the incident light.

Moreover, the third polarizing mirror distance (d31) may satisfy the following Mathematical Expression 9, and the third polarizing mirror distance (d31) may be one-fourth of the third wavelength (λ3).

$$d 31 = \frac{n \times λ 3 - bs 3}{2} \qquad Mathematical Expression 9$$

where d31 is the optical distance between the third light-emitting layer EML3 and the plurality of third reflectors RFB3, n is an integer, λ3 is the third wavelength, and bs3 is the third reflector phase shift amount.

The third mirror distance (d32) may satisfy the following Mathematical Expression 10, and the third mirror distance (d32) may be one-half of the third wavelength (λ3).

$$d 32 = \frac{( n + \frac{1}{2} ) \times λ 3 - ls 3}{2} \qquad Mathematical Expression 10$$

where d32 is the optical distance between the third light-emitting layer EML3 and the third reflective layer RFL3, n is an integer, λ3 is the third wavelength, and ls3 is the third reflective layer phase shift amount.

The third half-mirror distance (d33) may satisfy the following Mathematical Expression 11, and the third half-mirror distance (d33) may be one-half of the third wavelength (λ3).

$$d 33 = \frac{n \times λ 3}{2} \qquad Mathematical Expression 11$$

where d33 is the optical distance between the third light-emitting layer EML3 and the third cathode electrode CE3, n is an integer, and λ3 is the third wavelength.

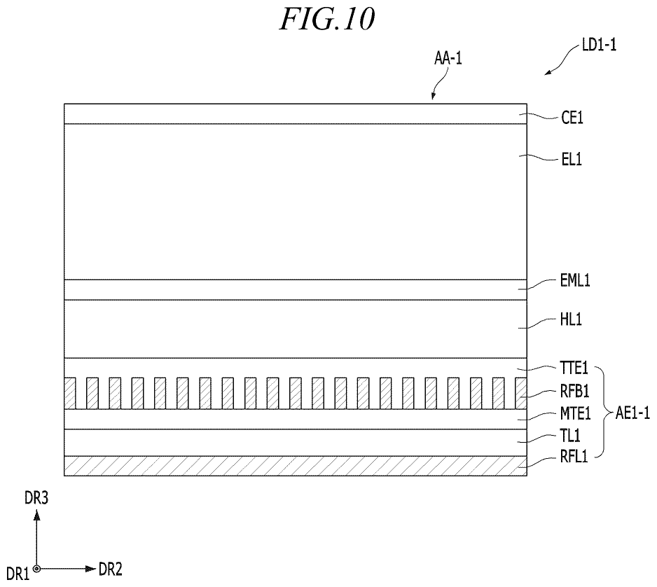

Hereinafter, one or more embodiments of the present disclosure will be described in more detail with reference to the drawings. FIG. 10 is an example illustration of a portion of the cross-section AA-1 of a first light-emitting diode LD1-1 according to one or more embodiments of the present disclosure. Referring to FIG. 10, a first anode electrode AE1-1 of the first light-emitting diode LD1-1 may further include a first middle transparent electrode MTE1.

The first middle transparent electrode MTE1 may be between the plurality of first reflectors RFB1 and the first reflective layer RFL1 and may have low resistance, allowing current to suitably (e.g., readily) flow. Moreover, the first middle transparent electrode MTE1 may be transparent. Accordingly, the first middle transparent electrode MTE1 may not interfere with the light emitted from the first light-emitting layer EML reaching and being reflected by the first reflective layer RFL1. In one or more embodiments, the first middle transparent electrode MTE1 may include indium tin oxide, providing the aforementioned material characteristics (e.g., low resistance and transparent). Furthermore, the first middle transparent electrode MTE1 may be arranged in contact with the plurality of first reflectors RFB1 to prevent or reduce the plurality of first reflectors RFB1 from corrosion.

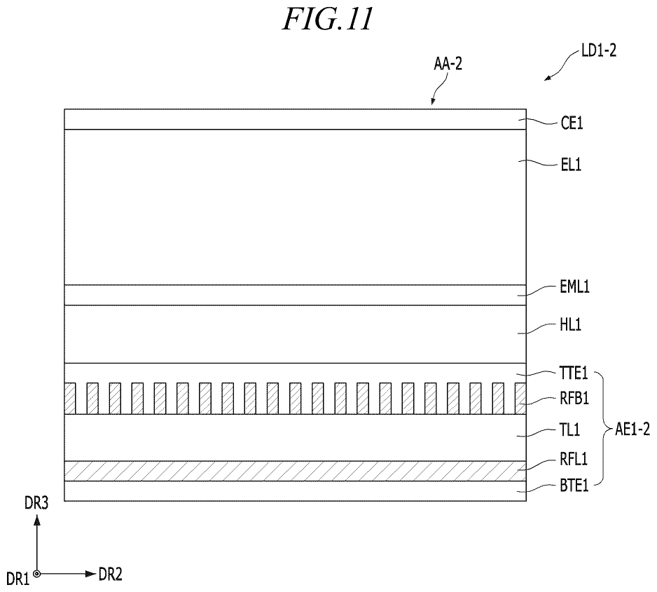

FIG. 11 is an example illustration of a portion of the cross-section AA-2 of a first light-emitting diode LD1-2 according to one or more embodiments of the present disclosure. Referring to FIG. 11, a first anode electrode AE1-2 of the first light-emitting diode LD1-2 may further include a first bottom transparent electrode BTE1. The first bottom transparent electrode BTE1 may be arranged beneath the first reflective layer RFL1 and may have low resistance, allowing current to suitably (e.g., readily) flow. The first bottom transparent electrode BTE1 may include indium tin oxide. Moreover, the first bottom transparent electrode BTE1 may be arranged in contact with the first reflective layer RFL1 to prevent or reduce the first reflective layer RFL1 from corrosion.

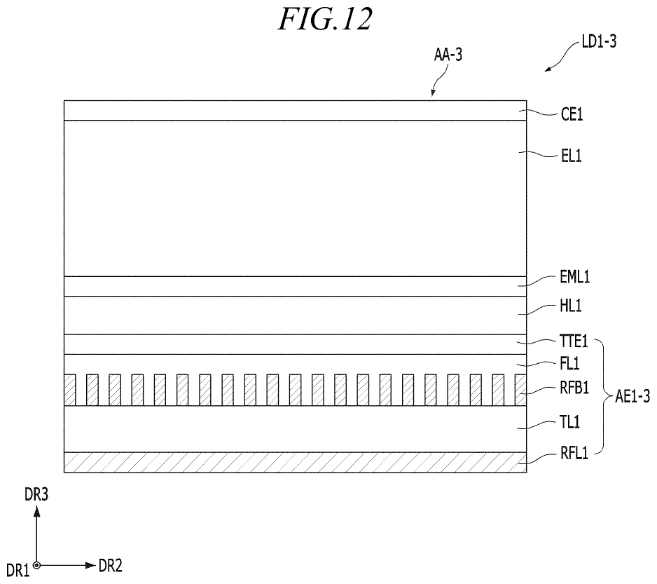

FIG. 12 is an example illustration of a portion of the cross-section AA-3 of a first light-emitting diode LD1-3 according to one or more embodiments of the present disclosure. Referring to FIG. 12, a first anode electrode AE1-3 of the first light-emitting diode LD1-3 may further include a first filler FL1. The first filler FL1 may be partially between two adjacent first reflectors of the plurality of first reflectors RFB1 and may also be partially arranged on the plurality of first reflectors RFB1. The first filler FL1 may be filled before the first top transparent electrode TTE1 is laminated, thereby providing greater structural stability to the plurality of first reflectors RFB1.

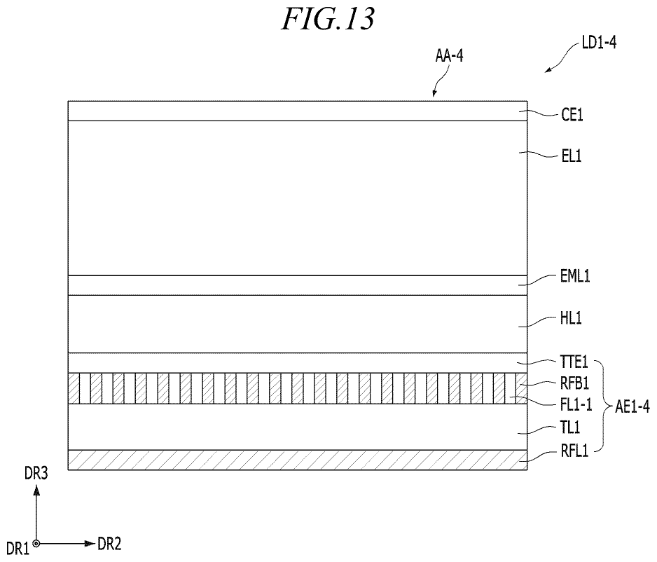

FIG. 13 is an example illustration of a portion of the cross-section AA-4 of a first light-emitting diode (LD1-4) according to one or more embodiments of the present disclosure. Referring to FIG. 13, a first anode electrode AE1-4 of the first light-emitting diode LD1-4 may further include a first filler FL1-1. The first filler FL1-1 may be between two adjacent first reflectors of the plurality of first reflectors RFB1. Before the first top transparent electrode TTE1 is laminated, the first filler FL1 (see FIG. 12) may be filled, as shown in FIG. 12, and then the top surface of the first filler FL1 may be planarized. Accordingly, the first filler FL1-1, as shown in FIG. 13, may be filled to provide greater structural stability to the plurality of first reflectors RFB1.

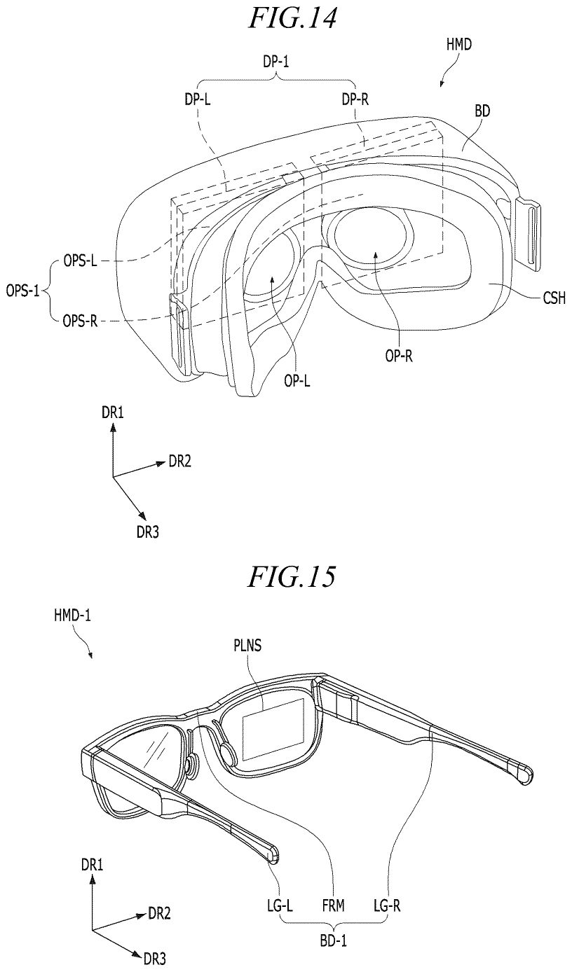

FIG. 14 is an example illustration of a body portion BD, a cushion portion CSH, a display panel DP-1, and an optical system OPS-1 of a display device HMD according to one or more embodiments of the present disclosure. Referring to FIG. 14, the display panel DP-1 may include a left display panel DP-L and a right display panel DP-R. Moreover, the optical system OPS-1 may include a left optical system OPS-L and a right optical system OPS-R. The left display panel DP-L may be arranged on the left side and may display a first image. The right display panel DP-R may be arranged on the right side and may display a second image. The left optical system OPS-L may be arranged on the left side and may be configured to guide the first image to the user's left eye. The right optical system OPS-R may be arranged on the right side and may be configured to guide the second image to the user's right eye.

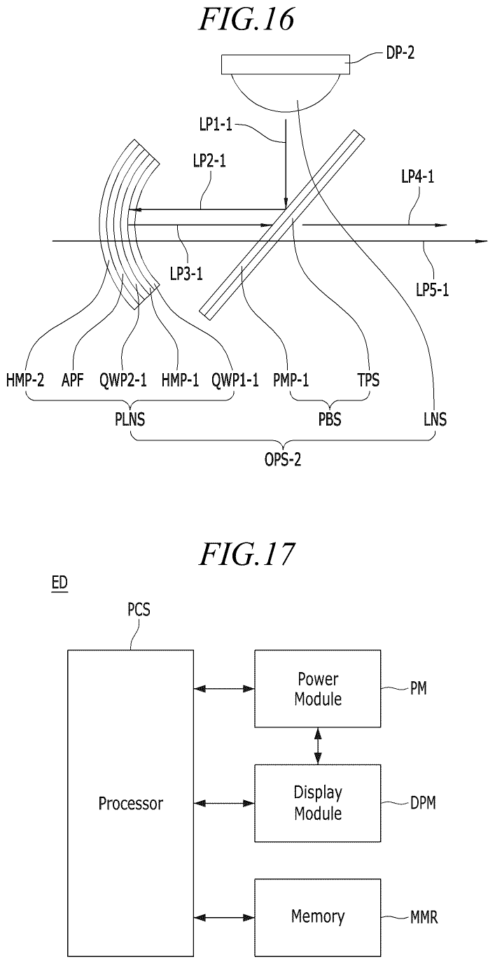

FIG. 15 is a perspective view of a display device HMD-1 according to one or more embodiments of the present disclosure. FIG. 16 is an example illustration of a portion of a display panel DP-2 and an optical system OPS-2 according to one or more embodiments of the present disclosure, as well as the path of light emitted from the display panel DP-2. Referring to FIG. 15, the display device HMD-1 may include a body portion BD-1 and a pancake lens PLNS, and the body portion BD-1 may include a frame portion FRM, a left leg portion LG-L, and a right leg portion LG-R. The body portion BD-1 may include the frame portion FRM in which the pancake lens PLNS is positioned, the left leg portion LG-L that is mounted on the user's left ear, and the right leg portion LG-R that is mounted on the user's right ear. A storage space may be defined within the body portion BD-1 to accommodate the display panel DP-2, a lens LNS, and a polarizing beam splitter PBS shown in FIG. 16. For example, the storage space may be defined within the left leg portion LG-L and the right leg portion LG-R. The pancake lens PLNS may be a part of the optical system OPS-2, which will be described in more detail later. The detailed configuration of the pancake lens PLNS is described with reference to FIG. 16.

Referring to FIG. 16, the optical system OPS-2 may include the lens LNS, the polarizing beam splitter PBS, and the pancake lens PLNS. The light emitted from the display panel DP-2 may travel along a first light path to a fourth light path LP1-1, LP2-1, LP3-1, LP4-1 and reach the eye of the user US. Additionally, natural light may travel along a fifth light path (LP5-1) and reach the user's (US) eye. The optical system OPS-2 shown in FIG. 16 may primarily be described in terms of its differences from the optical system OPS shown in FIG. 4.

The lens LNS may be configured to convert and project the light emitted from the display panel DP-2 to a beam form. The polarizing beam splitter PBS may include a transparent substrate TPS and a polarizing mirror PMP-1. The polarizing beam splitter PBS may be configured to reflect light oscillating in a set or predetermined direction from the beam projected by the lens LNS and allow light oscillating in a direction different from the set or predetermined direction to pass through. The polarizing mirror PMP-1 may be arranged on the transparent substrate TPS.

The pancake lens PLNS may include a first quarter-wave plate QWP1-1, a first half mirror HMP-1, a second quarter-wave plate QWP2-1, an absorbing polarizing film APF, and a second half mirror HMP-2. The absorbing polarizing film APF may be configured to absorb light oscillating in a set or predetermined direction and allow light oscillating in directions other than the set or predetermined direction to pass through. The absorbing polarizing film APF may be configured to prevent or reduce the light emitted from the display panel DP-2 from being externally exposed.

The light emitted from the display panel DP-2 may be converted to a beam form by the lens LNS and then be incident on the polarizing mirror PMP-1 along the first light path LP1-1. The light oscillating in a set or predetermined direction may then be reflected by the polarizing mirror PMP-1.

The light reflected by the polarizing mirror PMP-1 may pass through the first quarter-wave plate QWP1-1 along the second light path LP2-1. The light may then be reflected by the first half mirror HMP-1.

The light reflected by the first half mirror HMP-1 may pass through the first quarter-wave plate QWP1-1 again along the third light path LP3-1 and may then be incident on the polarizing mirror PMP-1. The light incident on the polarizing mirror PMP-1 along the third light path LP3-1 may have a different polarization direction than the light incident on the polarizing mirror PMP-1 along the first light path LP1-1. This is because the light passes through the first quarter-wave plate QWP1-1 twice in the course of traveling along the second light path LP2-1 and the third light path LP3-1. Therefore, the light incident on the polarizing mirror PMP-1 along the third light path LP3-1 may pass through the polarizing mirror PMP-1.

The light having passed through the polarizing mirror PMP-1 may travel along the fourth light path LP4-1 and be incident on the eye of the user US. As a result, the image displayed on the display panel DP-2 may be guided by the optical system OPS-2 and provided to the user US. Moreover, natural light from the outside may travel along the fifth light path LP5-1 and be incident on the eye of the user US. As a result, it becomes possible for the display device HMD-1 to implement augmented reality (AR).

For example, the configuration in the display device described in the embodiments referenced in FIGS. 1 to 16 may allow incident light to pass through the polarizing mirror PMP, PMP-1 to emit polarized light, such that the absorptive polarizing film may be excluded from the display panel and the display device. Therefore, a loss of the optical efficiency originally caused by the absorptive polarizing film may be prevented or reduced, and the optical efficiency of the display panel and the display device may be improved.

For example, according to one or more embodiments of the present disclosure, it is possible to provide a display panel that includes a light-emitting diode (LED) configured to emit polarized light. This approach eliminates the need for an absorptive polarizing film, which is traditionally used in display panels to achieve polarization. The absence of the absorptive polarizing film addresses the significant issue of light loss, as such films typically absorb about half of the emitted light, leading to reduced optical efficiency.

By integrating LEDs that inherently emit polarized light, the display panel may achieve higher optical efficiency. This improvement is beneficial for applications in head-mounted display devices, where reducing weight and size without compromising performance is crucial. The enhanced optical efficiency not only contributes to brighter and more vivid displays but also extends the battery life of portable devices by reducing the power consumption required to achieve the desired brightness levels.

Furthermore, the described embodiments detail the structural configuration of the LEDs, including the arrangement of anode and cathode electrodes, reflective layers, and transparent electrodes. These configurations are designed to enhance the emission and reflection of light, ensuring that the polarized light is efficiently utilized within the display panel. The precise control over the optical distances between various layers, as described in the mathematical expressions, further enhances the performance of the LEDs.

In summary, the present disclosure enhances display technology by offering a display panel with LEDs that emit polarized light, thereby eliminating the need for absorptive polarizing films and achieving improved optical efficiency. This advancement has the potential to revolutionize the design and performance of various electronic devices, including head-mounted displays, smartphones, tablets, and/or other portable devices.

According to one or more embodiments, a display apparatus in which the optical efficiency may be efficiently improved may be implemented. However, the scope of the disclosure is not limited by this effect.

FIG. 17 is an exemplary block diagram of an electronic device according to one or more embodiments.

Referring to FIG. 17, the electronic device ED according to one or more embodiments may include a display module DPM, a processor PCS, a memory MMR, and a power module PM.

The processor PCS may include at least one selected from among a central processing unit CPU, an application processor AP, a graphic processing unit GPU, a communication processor CP, an image signal processor ISP, and a controller.

The memory MMR may be provided to store data information to operate the processor PCS or the display module DPM. If (e.g., when) the processor PCS operates an application stored in the memory MMR, the display module DPM may be provided to receive an image data signal and/or an input control signal and process the received signal to provide an output of image information through a display screen.

A power module PM may include a power supply module, such as a power adapter and/or a battery device, and a power conversion module, which converts power supplied by the power supply module to generate power to operate an electronic device ED.

At least one of the elements of the electronic device ED as described in one or more embodiments may be included in the display device according to one or more embodiments. In one or more embodiments, one or more of individual modules functionally included in a single module may be included in the display device, and the other may be provided separately from the display device. For example, a display module may be included in the display device, and the processor PCS, the memory MMR, and the power module PM may be provided in a form of another device within the electronic device ED other than the display device.

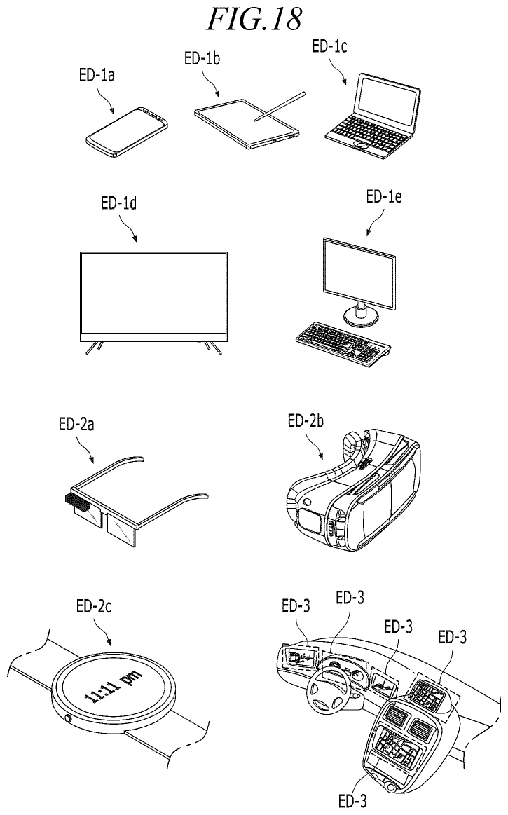

FIG. 18 illustrates schematic diagrams of electronic devices according to one or more embodiments.

Referring to FIG. 18, one or more suitable electronic devices having display devices according to one or more embodiments may include not only an image display electronic device, such as a smart phone ED-1a, a tablet PC ED-1b, a laptop ED-1c, a TV ED-1d, and a desk monitor ED-1e, but also a wearable electronic device including a display module, such as a smart glass ED-2a, a head mounted display ED-2b, and/or a smart watch ED-2c, and/or a vehicle electronic device ED-3 including a display module, such as a Center Information Display (CID) and/or a room mirror display on an instrument panel, center fascia, and/or a dashboard of an automobile.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display apparatus, a device of manufacturing a display apparatus, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While one or more embodiments of the present disclosure have been described above, a person ordinarily skilled in the art to which the present disclosure pertains shall appreciate that there may be a variety of modifications and permutations of the present disclosure without departing from the technical ideas and scopes of the present disclosure and equivalents thereof that are defined in the appended claims. Moreover, it shall be appreciated that the one or more embodiments of the present disclosure are not intended to restrict the present disclosure thereto and that every technical idea within the appended claims and their equivalents is interpreted to be included in the scope of the present disclosure and equivalents thereof.

What is claimed is:

1. A display panel comprising:
a plurality of light-emitting diodes,
wherein a first light-emitting diode among the plurality of light-emitting diodes comprises:
a first anode electrode comprising a first reflective layer, a plurality of first reflectors, and a first top transparent electrode, the first reflective layer being configured to reflect incident light, the plurality of first reflectors being on the first reflective layer, the first top transparent electrode being on the plurality of first reflectors, each of the plurality of first reflectors extending in a first direction, and the plurality of first reflectors being arranged in a second direction crossing the first direction;
a first light-emitting layer on the first anode electrode and configured to emit light having a first wavelength; and
a first cathode electrode on the first light-emitting layer and configured to transmit a portion of the incident light and reflect the other portion of the incident light.

2. The display panel of claim 1, wherein:
in a third direction orthogonal to the first direction and the second direction, an optical distance between the first light-emitting layer and the plurality of first reflectors is one-fourth of the first wavelength; and
in the third direction, an optical distance between the first light-emitting layer and the first reflective layer is one-half of the first wavelength.

3. The display panel of claim 2, wherein, in the third direction, an optical distance between the first light-emitting layer and the first cathode electrode is one-half of the first wavelength.

4. The display panel of claim 1, wherein:
a phase shift amount of light reflected by the plurality of first reflectors is defined as a first reflector phase shift amount (bs1);
a phase shift amount of light reflected by the first reflective layer is defined as a first reflective layer phase shift amount (ls1);
in a third direction orthogonal to the first direction and the second direction, an optical distance (d11) between the first light-emitting layer and the plurality of first reflectors satisfies Mathematical Expression 1; and
in the third direction, an optical distance (d12) between the first light-emitting layer and the first reflective layer satisfies Mathematical Expression 2,
$$d 11 = \frac{n \times λ 1 - bs 1}{2} , \qquad Mathematical Expression 1$$
wherein d11 is the optical distance between the first light-emitting layer and the plurality of first reflectors, n is an integer, λ1 is the first wavelength, and bs1 is the first reflector phase shift amount;
$$d 12 = \frac{( n + \frac{1}{2} ) \times λ 1 - ls 1}{2} , \qquad Mathematical Expression 2$$
and
wherein d12 is the optical distance between the first light-emitting layer and the first reflective layer, n is an integer, λ1 is the first wavelength, and ls1 is the first reflective layer phase shift amount.

5. The display panel of claim 4, wherein, in the third direction, an optical distance (d13) between the first light-emitting layer and the first cathode electrode satisfies Mathematical Expression 3,
$$d 13 = \frac{n \times λ 1}{2} , \qquad Mathematical Expression 3$$
and
wherein d13 is the optical distance between the first light-emitting layer and the first cathode electrode, n is an integer, and λ1 is the first wavelength.

6. The display panel of claim 1, wherein:
the first light-emitting diode further comprises a first transparent layer on the first reflective layer and being in contact with the first reflective layer;
the first top transparent electrode is in contact with the plurality of first reflectors;
a refractive index of the first reflective layer is higher than a refractive index of the first transparent layer; and
a refractive index of the first top transparent electrode is lower than a refractive index of the plurality of first reflectors.

7. The display panel of claim 1, wherein a first length of each of the plurality of first reflectors, measured in the second direction, is greater than or equal to 2.5 nm and smaller than or equal to 100 nm.

8. The display panel of claim 7, wherein a second length measured between two adjacent first reflectors among the plurality of first reflectors is greater than or equal to 2.5 nm and smaller than or equal to 100 nm.

9. The display panel of claim 8, wherein a ratio of the first length to the second length is greater than or equal to 0.95 and smaller than or equal to 1.05.

10. The display panel of claim 1, wherein the first anode electrode further comprises a first middle transparent electrode between the plurality of first reflectors and the first reflective layer.

11. The display panel of claim 1, wherein the first anode electrode further comprises a first bottom transparent electrode beneath the first reflective layer.

12. The display panel of claim 1, wherein a filler is between two adjacent first reflectors among the plurality of first reflectors.

13. The display panel of claim 3, wherein a second light-emitting diode among the plurality of light-emitting diodes comprises:
a second anode electrode comprising a second reflective layer configured to reflect second incident light, a plurality of second reflectors on the second reflective layer, and a second top transparent electrode on the plurality of second reflectors, wherein each of the plurality of second reflectors extends in the first direction, and the plurality of second reflectors are arranged in the second direction;
a second light-emitting layer on the second anode electrode and configured to emit light having a second wavelength different from the first wavelength; and
a second cathode electrode on the second light-emitting layer and configured to transmit a portion of the second incident light and reflect the other portion of the second incident light.

14. The display panel of claim 13, wherein:
in the third direction, an optical distance between the second light-emitting layer and the plurality of second reflectors is one-fourth of the second wavelength;
in the third direction, an optical distance between the second light-emitting layer and the second reflective layer is one-half of the second wavelength; and
in the third direction, an optical distance between the second light-emitting layer and the second cathode electrode is one-half of the second wavelength.

15. The display panel of claim 14, wherein a third light-emitting diode among the plurality of light-emitting diodes comprises:
a third anode electrode comprising a third reflective layer configured to reflect third incident light, a plurality of third reflectors on the third reflective layer, and a third top transparent electrode on the plurality of third reflectors, each of the plurality of third reflectors extending in the first direction, and the plurality of third reflectors being arranged in the second direction;
a third light-emitting layer on the third anode electrode and configured to emit light having a third wavelength different from the first wavelength and the second wavelength;
a third cathode electrode on the third light-emitting layer and configured to transmit a portion of the third incident light and reflect the other portion of the third incident light;
in the third direction, an optical distance between the third light-emitting layer and the plurality of third reflectors is one-fourth of the third wavelength;
in the third direction, an optical distance between the third light-emitting layer and the third reflective layer is one-half of the third wavelength; and
in the third direction, an optical distance between the third light-emitting layer and the third cathode electrode is one-half of the third wavelength.

16. A display device comprising:
a display panel, the display panel comprising a plurality of light-emitting diodes,
wherein a first light-emitting diode among the plurality of light-emitting diodes comprises:
a first anode electrode comprising a first reflective layer, a plurality of first reflectors, and a first top transparent electrode, the first reflective layer being configured to reflect incident light, the plurality of first reflectors being on the first reflective layer, the first top transparent electrode being on the plurality of first reflectors, each of the plurality of first reflectors extending in a first direction, and the plurality of first reflectors being arranged in a second direction crossing the first direction;
a first light-emitting layer on the first anode electrode and configured to emit light having a first wavelength; and
a first cathode electrode on the first light-emitting layer and configured to transmit a portion of the incident light and reflect the other portion of the incident light.

17. The display device of claim 16, wherein:
in a third direction orthogonal to the first direction and the second direction, an optical distance between the first light-emitting layer and the plurality of first reflectors is one-fourth of the first wavelength;
in the third direction, an optical distance between the first light-emitting layer and the first reflective layer is one-half of the first wavelength; and
in the third direction, an optical distance between the first light-emitting layer and the first cathode electrode is one-half of the first wavelength.

18. The display device of claim 17, further comprising an optical system configured to receive light emitted from the display panel,
wherein the optical system comprises:
a half-mirror lens comprising a half mirror configured to reflect a portion of the received light and transmit the other portion of the received light; and
a polarizing mirror lens comprising a polarizing mirror and a quarter-wave plate, the polarizing mirror being configured to reflect light oscillating in a set direction and transmit light oscillating in a direction different from the set direction, the quarter-wave plate being configured to change a polarization direction of the received light, and
wherein the quarter-wave plate is between the polarizing mirror and the half-mirror lens.

19. The display device of claim 17, further comprising an optical system configured to receive light emitted from the display panel,
wherein the optical system comprises:
a pancake lens comprising a half-mirror lens and a quarter-wave plate, the half-mirror lens being configured to reflect a portion of the received light and transmit the other portion of the received light, the quarter-wave plate being configured to change the polarization direction of the received light; and
a polarizing mirror configured to reflect light among the received light oscillating in a set direction and transmit light among the received light oscillating in a direction different from the set direction, and
wherein the quarter-wave plate is between the polarizing mirror and the half-mirror lens.

20. An electronic device comprising a display device comprising:
a display panel comprising:
a plurality of light-emitting diodes,
wherein a first light-emitting diode among the plurality of light-emitting diodes comprises:
a first anode electrode comprising a first reflective layer, a plurality of first reflectors, and a first top transparent electrode, the first reflective layer being configured to reflect incident light, the plurality of first reflectors being on the first reflective layer, the first top transparent electrode being on the plurality of first reflectors, each of the plurality of first reflectors extending in a first direction, and the plurality of first reflectors being arranged in a second direction crossing the first direction;
a first light-emitting layer on the first anode electrode and configured to emit light having a first wavelength; and
a first cathode electrode on the first light-emitting layer and configured to transmit a portion of the incident light and reflect the other portion of the incident light.
